(19) United States
(12) Patent Application Publication
(10) Pub. No.: US 2015/0122643 A1
(43) Pub. Date: May 7, 2015

(54) SUPPORTING MEMBER FOR MAGNETRON SPUTTERING ANODE BAR AND MAGNETRON SPUTTERING DEVICE INCLUDING THE SAME

(71) Applicant: Shenzhen China Star Optoelectronics Technology Co., Ltd., Shenzhen, Guangdong (CN)

(72) Inventor: Jinping Xie, Shenzhen (CN)

(21) Appl. No.: 14/241,338

(22) PCT Filed: Jan. 24, 2014
(86) PCT No.: PCT/CN2014/071416

§ 371 Date: Feb. 26, 2014

(30) Foreign Application Priority Data
Nov. 6, 2013 (CN) 201310545471.6

(51) Int. Cl. C23C 14/35; H01J 37/34

(52) U.S. Cl. CPC C23C 14/35; H01J 37/3408; H01J 37/3438
USPC 204/298.14

(57) ABSTRACT

The present disclosure relates to a supporting member for a magnetron sputtering anode bar and a magnetron sputtering device including the supporting member. The supporting member comprises a supporting bar and a sputtering shield which can be fixedly connected with the supporting bar. A first end portion of the supporting bar is configured as a supporting end in cooperation with the anode bar, and a second end portion is configured as a mounting end which can be fixedly connected with a mounting hole of the sputtering shield so as to prevent the supporting bar from falling off the mounting hole. The cross section of the mounting end is smaller relative to that of the main body portion of the supporting bar. The supporting bar of the supporting member according to the present disclosure can be fixedly connected with the sputtering shield without accidental detachment.

### FIELD OF THE INVENTION

The present disclosure relates to film-coating equipment, in particular to a supporting member for a magnetron sputtering anode bar. The present disclosure further relates to a magnetron sputtering device including the supporting member.

### BACKGROUND OF THE INVENTION

Magnetron sputtering technology is commonly used in film coating, and has the advantages of high film-forming rate, low substrate temperature, good film adhesion, and the capability to realize large-area film coating, and the like.

In the vacuum cavity of the magnetron sputtering equipment for a cylindrical target, an anode bar needs to be arranged beside the cylindrical target so as to generate a film layer with good uniformity on a substrate. In the prior art, the anode bar is generally a stainless steel bar, wherein one end thereof is connected with the cavity, and the other end is supported by a supporting bar.

FIG. 1 schematically shows the supporting bar 110 used in the prior art. One end of the supporting bar 110 is connected with the anode bar 300, and the other end 120 thereof is inserted in a hole 210 in an sputtering shield 200, so that the supporting bar 110 can support the anode bar 300. However, such connection between the supporting bar 110 and the sputtering shield 200 is unstable, which can frequently lead to accidental detachment, thus causing equipment malfunction.

### SUMMARY OF THE INVENTION

To solve the technical problems in the prior art, the present disclosure proposes a supporting member for a magnetron sputtering anode bar, which is capable of firmly connecting the supporting bar with the sputtering shield without accidental detachment. The present disclosure further relates to a magnetron sputtering device including the supporting member.

(1) According to a first aspect of the present disclosure, a supporting member for a magnetron sputtering anode bar is provided. The supporting member comprises a supporting bar and a sputtering shield which can be fixedly connected with the supporting bar. A first end portion of the supporting bar is configured as a supporting end which can be in cooperation with the anode bar, and a second end portion is configured as a mounting end which can be fixedly connected with a mounting hole of the sputtering shield so as to prevent the supporting bar from falling off the mounting hole. The cross section of the mounting end is smaller relative to that of a main body portion of the supporting bar.

According to the supporting member of the present disclosure, the supporting bar can be fixedly connected with the sputtering shield through the mounting hole thereon, thus preventing the supporting bar from falling off the sputtering shield.

(2) In one embodiment of (1) according to the present disclosure, a diameter-reducing part of the mounting end of the supporting bar forms a right-angled step. The supporting bar and the mounting hole on the sputtering shield can be solidly clamped together through the right-angled step, thus improving the mounting stability of the supporting bar. Preferably, the diameter of the mounting hole is larger than or equal to that of the mounting end and smaller than the outer diameter of the right-angled step.

(3) In one of the embodiments of (1) or (2) according to the present disclosure, the supporting bar is cylindrical. In a preferred embodiment, the mounting end of the supporting bar is cylindrical, and the mounting hole on the sputtering shield is a circular hole matching the mounting end. The cylindrical supporting bar renders the manufacturing thereof relatively convenient. The mounting end of the supporting bar and the mounting hole are also circular, thus there is no specific requirements for the mounting direction between the supporting bar and the mounting hole, so as to facilitate the assembly therebetween.

(4) In any one of the embodiments of (1) to (3) according to the present disclosure, an insulation ring is further arranged between the supporting end of the supporting bar and the anode bar.

(5) In one embodiment of (4) according to the present disclosure, the insulation ring is made from ceramic. The ceramic insulation ring is high-temperature resistant and age resistant, thus avoiding the problems of carbonization or easy aging of a polymer insulation ring in the prior art. In one embodiment, the supporting bar is made from ceramic. Compared with the stainless steel supporting bar in the prior art, the ceramic supporting bar has better high temperature resistance. In a preferable embodiment, the ceramic is aluminum oxide ceramic.

(6) In any one of the embodiments of (1) to (5) according to the present disclosure, the end portion of the anode bar, which is in cooperation with the supporting bar, is configured as a hollow structure. The supporting end of the supporting bar is inserted in the hollow structure, and the insulation ring is placed between the supporting end and the inner wall of the hollow structure.

7) According to a second aspect of the present disclosure, a magnetron sputtering device comprising the supporting member is proposed.

Compared with the prior art, the present disclosure has the advantage that the mounting hole is formed in the sputtering shield, and the mounting end of the supporting bar can be placed in the mounting hole through snap-fitting. Therefore, the supporting bar can be fixedly connected with the sputtering shield, and the supporting bar can be prevented from falling off the sputtering shield. The insulation ring made from ceramic can improve the high-temperature resistance of the insulation ring, and prolong the service life thereof. The supporting bar can also be made from ceramic, so that the high-temperature resistance thereof can be improved.

### BRIEF DESCRIPTION OF THE DRAWINGS

The present disclosure will be described in more detail below based on the embodiments with reference to the accompanying drawings, in which:

FIG. 1 schematically shows the structure of a supporting member in the prior art;

FIG. 2 schematically shows the structure of a supporting member according to the present disclosure.

In the accompanying drawings, the same components use the same reference signs. The accompanying drawings are not drawn to actual scale.

### DETAILED DESCRIPTION OF THE EMBODIMENTS

The present disclosure will be further illustrated below in conjunction with the accompanying drawings.

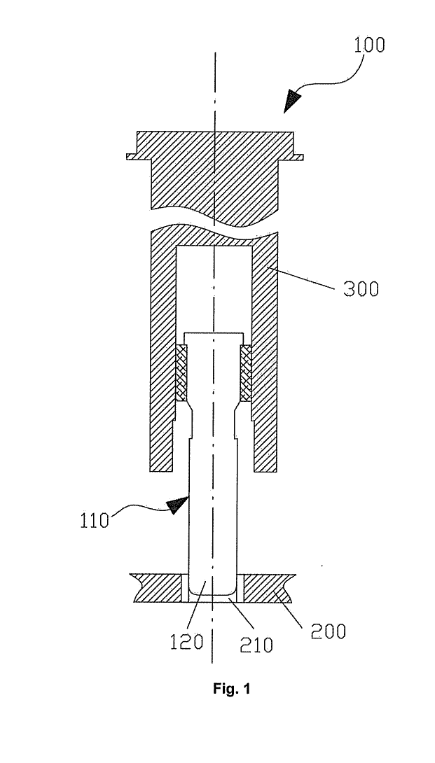

FIG. 1 schematically shows the connection of the supporting bar 110 with the anode bar 300 and the sputtering shield 200 in the prior art, which will not be described in detail.

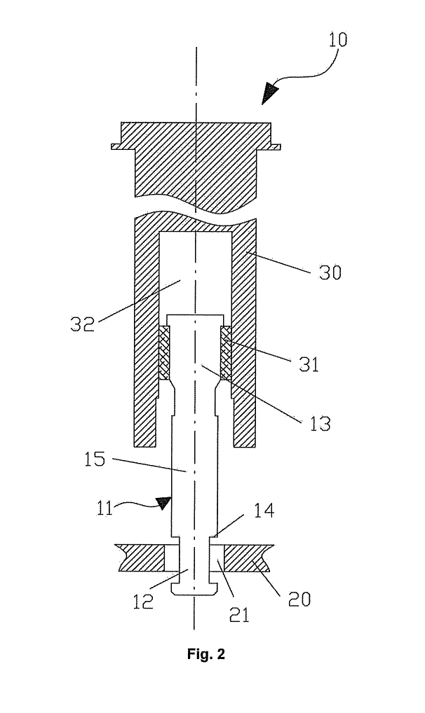

FIG. 2 schematically shows the supporting member 10 for the magnetron sputtering anode bar according to the present disclosure. The supporting member 10 comprises a supporting bar 11 and a sputtering shield 20 which can be fixedly connected together. As shown in FIG. 2, the first end portion of the supporting bar 11 is configured as a mounting end 12, the cross section of which is smaller than that of a main body portion 15 of the supporting bar 11. The second end portion of the supporting bar 11 is configured as a supporting end 13 in cooperation with an anode bar 30. A mounting hole 21, the shape and size of which match with those of the mounting end 12 of the supporting bar 11 respectively, is formed in the sputtering shield 20, so that the supporting bar 11 and the sputtering shield 20 can be easily assembled together.

To enable the machining and manufacturing of the supporting bar 11 to be easier, in one embodiment, the supporting bar 11 is shaped cylindrical. Accordingly, the mounting end 12 and the supporting end 13 of the supporting bar 11 are also cylindrical. In this case, the cross section of the mounting end 12 is smaller than that of the main body portion 15 of the supporting bar 11, i.e. the diameter of the mounting end 12 is smaller relative to that of the main body portion 15 of the supporting bar 11. In addition, the mounting hole 21 in the sputtering shield 20 is also formed as a circular hole matching with the mounting end 12 of the supporting bar 11. It should be understood that the mounting end 12 can also be in other shapes, such as a polygon, etc., and the shape of the mounting hole 21 can be the same as the mounting end 12. However, other shapes may be inconvenient in assembling the mounting end 12 and the mounting hole 21. Therefore, preferably, the mounting end 12 is configured to be cylindrical and the mounting hole 21 to be circular.

Preferably, the diameter-reducing part of the mounting end 12 forms a right-angled step 14, and the diameter of the mounting hole 21 is larger than or equal to that of the mounting end 12 and smaller than the outer diameter of the right-angled step 14. In this way, when being assembled, the supporting bar 11 can be firmly connected with the sputtering shield 20 through the snap joint between the right-angled step 14 and the mounting hole 21. When being assembled, the supporting bar 11 should be lifted, and then the mounting end 12 of the supporting bar 11 is inserted into the mounting hole 21 of the sputtering shield 20 to finish the assembly.

As shown in FIG. 2, the lower end of the anode bar 30 is configured as a hollow structure 32. When being assembled, the supporting end 13 of the supporting bar 11 can be inserted into the hollow structure 32, so as to support the anode bar 30. An insulation ring 31 can be further arranged between the supporting end 13 of the supporting bar 11 and the anode bar 30.

In order to improve the high-temperature resistance of the insulation ring 31, in one embodiment, the insulation ring 31 can be made from ceramic, such as aluminum oxide ceramic. The insulation ring 31 made from ceramic has better high-temperature resistance compared with an insulation ring made from polyether-ether-ketone (PEEK) in the prior art, and thus can effectively eliminate the problem of carbonization under high temperature. In addition, the service life of the ceramic insulation ring 31 is longer. In another embodiment, the supporting bar 11 can also be made from ceramic, such as aluminum oxide ceramic, so as to improve the high-temperature resistance of the supporting bar 11.

The present disclosure further relates to a magnetron sputtering device (not shown) including the supporting member 10 as shown in FIG. 2. Because the supporting member 10 according to the present disclosure is used, the service life of the magnetron sputtering device can be prolonged correspondingly, and the probability that the supporting bar 11 falls off the sputtering shield 20 can be lower.

Although the present disclosure has been described with reference to the preferred examples, various modifications could be made to the present disclosure without departing from the scope of the present disclosure and components in the present disclosure could be substituted by equivalents. Particularly, as long as there is no structural conflict, all the technical features mentioned in all the embodiments may be combined together in any manner. The present disclosure is not limited to the specific examples disclosed in the description, but includes all the technical solutions falling into the scope of the claims.

1. A supporting member for a magnetron sputtering anode bar, comprising a supporting bar, and a sputtering shield which can be fixedly connected with the supporting bar,
wherein a first end portion of the supporting bar is configured as a supporting end which can be in cooperation with the anode bar, and a second end portion thereof is configured as a mounting end which can be fixedly connected with a mounting hole of the sputtering shield so as to prevent the supporting bar from falling off the mounting hole of the sputtering shield, the cross section of the mounting end being smaller relative to that of a main body portion of the supporting bar.

2. The supporting member according to claim 1, wherein a diameter-reducing part of the mounting end of the supporting bar forms a right-angled step, and the diameter of the mounting hole is larger than or equal to that of the mounting end and smaller than the outer diameter of the right-angled step.

3. The supporting member according to claim 2, wherein the supporting bar is cylindrical.

4. The supporting member according to claim 3, wherein the mounting end of the supporting bar is cylindrical, and the mounting hole on the sputtering shield is a circular hole matching the mounting end.

5. The supporting member according to claim 2, wherein an insulation ring is further arranged between the supporting end of the supporting bar and the anode bar.

6. The supporting member according to claim 5, wherein the insulation ring is made from ceramic.

7. The supporting member according to claim 5, wherein the supporting bar is made from ceramic.

8. The supporting member according to claim 7, wherein the ceramic is aluminum oxide ceramic.

9. The supporting member according to claim 8, wherein the end portion of the anode bar, which cooperates with the supporting bar, is configured as a hollow structure; and
the supporting end of the supporting bar is inserted in the hollow structure, and the insulation ring is located between the supporting end and the inner wall of the hollow structure.

10. A magnetron sputtering device including a supporting member, which comprises a supporting bar, and a sputtering shield which can be fixedly connected with the supporting bar,
wherein a first end portion of the supporting bar is configured as a supporting end which can be in cooperation with the anode bar, and a second end portion thereof is configured as a mounting end which can be fixedly connected with a mounting hole of the sputtering shield so as to prevent the supporting bar from falling off the mounting hole of the sputtering shield, the cross section of the mounting end being smaller relative to that of a main body portion of the supporting bar.
